(19) United States
(12) Patent Application Publication
(10) Pub. No.: US 2006/0239060 A1
(43) Pub. Date: Oct. 26, 2006

(54) Semiconductor memory device and method for operating the same

(75) Inventor: Yasuhiro Shimada, Kyoto (JP)

Correspondence Address: PANASONIC PATENT CENTER;c/o MCDERMOTT WILL & EMERY LLP, 600 13TH STREET, NW, WASHINGTON, DC, 20005-3096, US

(73) Assignee: MATSUSHITA ELECTRIC INDUSTRIAL CO., LTD.

(21) Appl. No.: 11/405,452

(22) Filed: Apr. 18, 2006

(30) Foreign Application Priority Data
Apr. 18, 2005 (JP) 2005-120253

(51) Int. Cl. G11C 11/22

(52) U.S. Cl. 365/145

(57) ABSTRACT

A semiconductor memory device includes: a multilayer film including a first ferroelectric film and a second ferroelectric film; means for creating an electric field which goes vertically across the multilayer film; and means for passing current along an interface between the first ferroelectric film and the second ferroelectric film and detecting the current.

### CROSS-REFERENCE TO RELATED APPLICATION

This application claims priority under 35 USC §119 to Japanese Patent Application No. 2005-120253 filed on Apr. 18, 2005, the entire contents of all of which are incorporated herein by reference.

### BACKGROUND OF THE INVENTION

The present invention relates to a semiconductor memory device in which a ferroelectric film is used, and a method for operating the semiconductor memory device.

Ferroelectric memories having a MFS (Metal-Ferroelectric-Semiconductor) structure have been examined for a long time. A ferroelectric memory having the MFS structure is a semiconductor memory device that includes a ferroelectric gate electrode formed over a semiconductor substrate having a source and a drain so as to extend between the source and the drain, and the MFS structure allows resistance at the semiconductor substrate surface between the source and the drain to be modulated in accordance with the direction of spontaneous polarization in a ferroelectric film (see, for example, J. L. Moll and Y. Tarui, IEEE Electron Devices, Vol. ED-10, p. 338 (1963), S.-Y. Wu, IEEE Electron Devices, Vol. ED-21, p. 499 (1974)).

A ferroelectric memory having the MFS structure, which is capable of reading data without reversal of spontaneous polarization, i.e., capable of so-called non-destructive read-out, does not have the potential problem of polarization reversal fatigue occurring in the ferroelectric film caused by reading operations. Also, this structure, allowing a single device having a transistor structure including a source, a drain and a gate to store a single bit of data, is expected to be suitable for high degree of integration.

In recent years, as semiconductor memory devices using ferroelectric films have been integrated with higher density and have been offering higher performance and higher-speed operation, many types of ferroelectric memories, which have a structure similar to the MFS structure and are capable of non-destructive read-out, have been proposed (see Japanese Laid-Open Publication No. 5-90599, for example). In those memories, particularly because a ferroelectric film is directly connected to a semiconductor substrate, various considerations have been made so as to prevent irregularities at the semiconductor substrate surface caused mainly by oxidization resulting from the ferroelectric material.

As one approach to overcoming the instability occurring at the interface between the ferroelectric film and the semiconductor substrate, a technique has been proposed, in which a ferroelectric film and an insulating film both stable toward oxidation are connected so as to modulate resistance at the interface between the ferroelectric film and the insulating film by spontaneous polarization in the ferroelectric film (see Japanese Laid-Open Publication No. 2003-332538, for example).

Hereinafter, a conventional ferroelectric memory device will be described with reference to FIGS. 6 to 10. A description will be particularly made of a method for modulating resistance at the interface between a ferroelectric film and an insulating film by spontaneous polarization in the ferroelectric film. FIG. 6 shows a cross-sectional structure for a main part of the conventional ferroelectric memory device.

As shown in FIG. 6, a conductive film 102 made of metal or conductive metallic oxide is formed on a substrate 101 made of semiconductor material such as silicon. On the conductive film 102, an insulating film 103 made of SiO², SiOₓN_{y} or the like is formed. On the insulating film 103, a source electrode 104 and a drain electrode 105 are disposed. On the insulating film 103, a ferroelectric film 106 is formed so as to cover the source electrode 104 and the drain electrode 105. On the ferroelectric film 106, a gate electrode 107 is provided in a region extending between the source electrode 104 and the drain electrode 105.

In the ferroelectric memory device thus structured, the interface between the ferroelectric film 106 and the insulating film 103 is the channel between the source electrode 104 and the drain electrode 105.

A method for operating the conventional semiconductor memory device having the above structure will be described below with reference to FIGS. 7 to 10. FIGS. 7 to 10 are schematic views for explaining the method for operating the conventional ferroelectric memory device.

(Write Operation)

Data write to the ferroelectric memory device shown in FIG. 6 is performed as follows. A positive or negative pulse voltage is applied between the gate electrode 107 and the conductive film 102 to induce spontaneous polarization in the ferroelectric film 106. The direction of the spontaneous polarization induced in the ferroelectric film 106 is determined by the polarity of the pulse voltage applied between the gate electrode 107 and the conductive film 102.

For instance, as shown in FIG. 7, if a positive pulse voltage (+Vₐₚₚ) is applied to the gate electrode 107 with the potential at the conductive film 102 being ground potential (GND), spontaneous polarization 110 with electric charge P (C/cm²) per unit area is induced in the ferroelectric film 106, while dielectric polarization 120 with electric charge Q (C/cm²) per unit area is induced in the insulating film 103.

Next, as shown in FIG. 8, the potential at the gate electrode 107 is set to the ground potential (GND). This causes electrons 130 to be injected from the source electrode 104 and the drain electrode 105, whereby the electric charge of the downward spontaneous polarization 110 at the interface between the ferroelectric film 106 and the insulating film 103 is compensated for. As a result, the potential difference between the interface between the ferroelectric film 106 and the insulating film 103 and the conductive film 102 is reduced gradually. Finally, as shown in FIG. 9, the electric charge of the downward spontaneous polarization 110 at the interface between the ferroelectric film 106 and the insulating film 103 is all compensated for by the electrons 130. At this time, the electric charge of the spontaneous polarization 110 is ionic and thus cannot move. Therefore, the electric charge capable of moving at the interface between the ferroelectric film 106 and the insulating film 103 is only those electrons 130 that have been coupled to the spontaneous polarization 110.

On the other hand, if a negative pulse voltage (−Vₐₚₚ) is applied to the gate electrode 107 with the potential at the conductive film 102 being the ground potential (GND), spontaneous polarization 110 with electric charge −P (C/cm²) per unit area is induced in the ferroelectric film 106, while dielectric polarization 120 with electric charge −Q (C/cm²) per unit area is induced in the insulating film 103. Thereafter, as shown in FIG. 10, the potential at the gate electrode 107 is set to the ground potential (GND), whereby atoms in the vicinity of the interface between the ferroelectric film 106 and the insulating film 103 release electrons and are ionized positively. These positively ionized atoms 200 compensate for the electric charge of the upward spontaneous polarization 110. In this case, the electrons released from the atoms flow into the source electrode 104 and The drain electrode 105. Consequently, only the positively ionized atoms 200 and the ionic electric charge of the spontaneous polarization 110 are left at the interface between the ferroelectric film 106 and the insulating film 103. Therefore, there is no electric charge that can move at the interface between the ferroelectric film 106 and the insulating film 103.

(Read Operation)

Next, data read from the ferroelectric memory device will be described. The conduction state (i.e., the number of movable electric charges) in the channel changes depending upon the direction of the spontaneous polarization 110 in the ferroelectric film 106. It is therefore possible to determine whether the direction of the spontaneous polarization 110 is upward (which means that a voltage negative with respect to the conductive film 102 was applied to the gate electrode 107 to perform the write operation) or downward (which means that a voltage positive with respect to the conductive film 102 was applied to the gate electrode 107 to perform the write operation) by reading changes in the resistance of the channel current when a bias voltage is applied between the source electrode 104 and the drain electrode 105.

More specifically, when the direction of the spontaneous polarization 110 is upward, the number of movable electrons existing at the interface between the ferroelectric film 106 and the insulating film 103 is small, which results in increase in the channel resistance. On the other hand, when the direction of the spontaneous polarization 110 is downward, many movable electrons are present at the interface between the ferroelectric film 106 and the insulating film 103, which results in decrease in the channel resistance. In this manner, the channel current is changed depending upon the direction of the spontaneous polarization 110. It is thus possible to determine the direction of the spontaneous polarization 110.

It has been reported in Japanese Laid-Open Publication No. 7-326683 that even in cases where conductive oxide such as SrTiO₃ is used instead of the insulating film 103, effects similar to those mentioned above are expected to be achieved.

Nevertheless, in the case of the conventional ferroelectric; memory device, a problem occurs in that the carrier density in the electric charge movable in the channel is at most almost the same as the spontaneous polarization and is not sufficiently high as the magnitude of the channel current required for read operation.

Specifically, assume that the spontaneous polarization has a typical value of about 10 μC/cm². In this case, the carrier density in the electric charge in the channel is about 10¹⁴/cm², thereby achieving the electric charge density close to the electric charge density obtained at metal surfaces. However, the electric charge carriers for compensating for the electric charge of the spontaneous polarization are strongly confined by the electric charge of the spontaneous polarization It is therefore not easy to interchange the electric charge carriers for compensating for the electric charge of the spontaneous polarization and adjacent electric charge carriers coupled to the electric charge of the spontaneous polarization. In other words, the wave functions for the electric charge compensating for the electric charge of the spontaneous polarization are localized.

### SUMMARY OF THE INVENTION

In view of the above, it is therefore an object of the present invention to increase localized electric charge carrier density so as to obtain a sufficient amount of channel current.

In order to achieve the object, a semiconductor memory device in one aspect of the present invention includes; a multilayer film including a first ferroelectric film and a second ferroelectric film; means for creating an electric field which goes across the multilayer film; and means for passing current along an interface between the first ferroelectric film and the second ferroelectric film and detecting the current.

In the semiconductor memory device in the one aspect of the present invention, it is possible to induce, as carriers, electric charge that is equal in amount to the total amount of spontaneous polarization in the first ferroelectric film and spontaneous polarization in the second ferroelectric film at the interface between the first and second ferroelectric films. This allows a sufficient amount of channel current to be obtained. Therefore, even if the carriers induced at the interface between the first and second ferroelectric films are confined and localized by the electric charge of the spontaneous polarization in the first and second ferroelectric films, the amount of overlap between the wave functions is increased by the fact that the distance between adjacent carriers is shortened as compared with the conventional example, whereby the adjacent carriers are interchanged easily. As a result, the localized electric charge carrier density is increased and a sufficient amount of channel current is thus obtained.

In the semiconductor memory device in another aspect of the present invention, coercive voltage for the first ferroelectric film and coercive voltage for the second ferroelectric film are preferably different from each other.

Then, it is possible to reverse the spontaneous polarity only in the first or second ferroelectric film. Therefore, the carriers induced by the spontaneous polarization in the first ferroelectric film and the carriers induced by the spontaneous polarization in the second ferroelectric film can be efficiently added together.

In the semiconductor memory device in still another aspect of the present invention, the means for creating an electric field preferably includes a pair of electrodes provided so as to face each other with the multilayer film interposed therebetween.

Then, by the simple structure, an electric field going vertically across the multilayer film can be created.

In the semiconductor memory device in yet another aspect of the present invention, the means for passing current along the interface and detecting the current is preferably electrically connected to the first ferroelectric film or the second ferroelectric film and preferably includes a pair of electrodes, in between the interface along which the current passes exists.

Then, by the simple structure, the current passing along the interface can be detected.

In a method for operating a semiconductor memory device in one aspect of the present invention, modulation of current passing along an interface in a multilayer film is used; and the current modulation is performed by creating an electric field, which goes across the multilayer film including a first ferroelectric film and a second ferroelectric film having different coercive voltages, and by reversing spontaneous polarization in either one of the first ferroelectric film and the second ferroelectric film.

According to the semiconductor memory device operation method in the one aspect of the present invention, it is possible to efficiently add the carriers induced by the spontaneous polarization in the first ferroelectric film and the carriers induced by the spontaneous polarization in the second ferroelectric film together. It is thus possible to obtain the added carriers at the interface between the first and second ferroelectric films, thereby obtaining a sufficient amount of channel current.

In the semiconductor memory device operation method in another aspect of the present invention, before the spontaneous polarization in either one of the first ferroelectric film and the second ferroelectric film is reversed, spontaneous polarization is preferably induced in the other one of the first ferroelectric film and the second ferroelectric film, whose spontaneous polarization induced is never reversed independent of the polarization reversal of the other ferroelectric film

Then, carriers for compensating for the electric charge of the spontaneous polarization induced beforehand in the second ferroelectric film in which the spontaneous polarization is not to be reversed can be used as the channel current.

As described above, in the semiconductor memory device and the method for operating the semiconductor memory device in the one aspect of the present invention, the interface between the first ferroelectric film and the second ferroelectric film is the channel, and after the spontaneous polarization in one of the ferroelectric films is fixed, the spontaneous polarization in the other ferroelectric films is reversed in accordance with data, whereby a large amount of channel current can be obtained when non-destructive read-out is performed. It is thus possible to realize data retention characteristic that is stable for a long time.

### BRIEF DESCRIPTION OF THE DRAWINGS

FIG. 1 shows a cross-sectional structure for a main part of a semiconductor memory device according to an embodiment of the present invention.

FIG. 2 is a schematic cross-sectional view for explaining a method for operating the semiconductor memory device according to the embodiment of the present invention

FIG. 3 is a schematic cross-sectional view for explaining the semiconductor memory device operation method according to the embodiment of the present invention.

FIG. 4 is a schematic cross-sectional view for explaining the semiconductor memory device operation method according to the embodiment of the present invention.

FIG. 5 is a schematic cross-sectional view for explaining the semiconductor memory device operation method according to the embodiment of the present invention.

FIG. 6 shows a cross-sectional structure for a main part of a conventional semiconductor memory device.

FIG. 7 is a schematic cross-sectional view for explaining a method for operating the conventional semiconductor memory device.

FIG. 8 is a schematic cross-sectional view for explaining the conventional semiconductor memory device operation method.

FIG. 9 is a schematic cross-sectional view for explaining the conventional semiconductor memory device operation method.

FIG. 10 is a schematic cross-sectional view for explaining the conventional semiconductor memory device operation method.

### DETAILED DESCRIPTION OF THE INVENTION

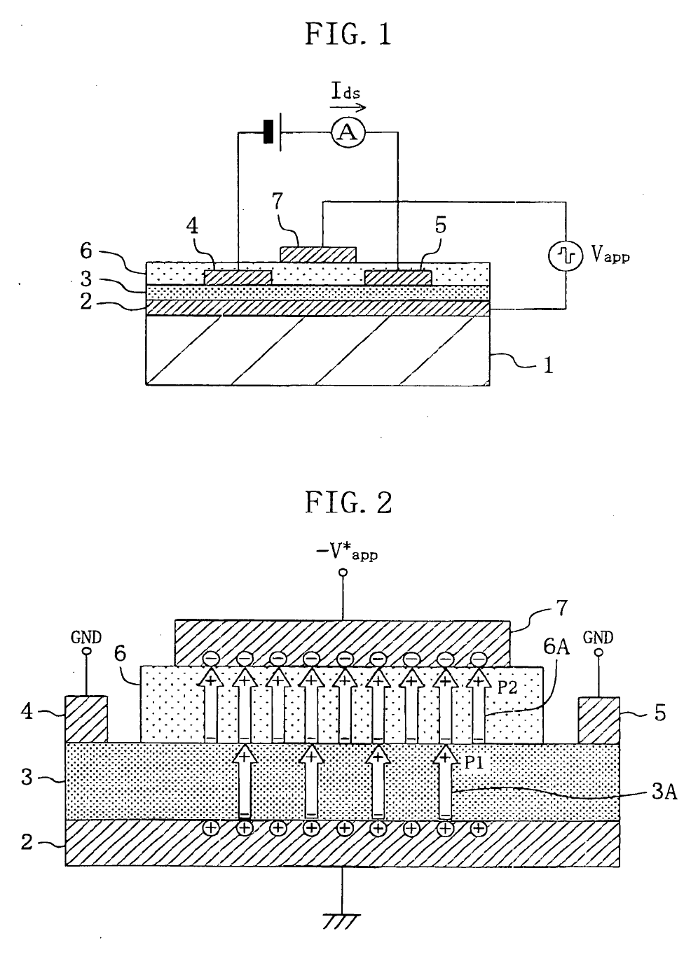

Hereinafter, a semiconductor memory device according to an embodiment of the resent invention will be described with reference to FIGS. 1 to 5. FIG. 1 shows a cross-sectional structure for a main part of the semiconductor memory device according to the embodiment of the present invention.

(Structure of the Semiconductor Memory Device)

As shown in FIG. 1, a conductive film 2 made of metal or conductive metallic oxide is formed on a substrate 1 made of semiconductor material such as silicon. On the conductive film 2, a first ferroelectric film 3 is formed. On the first ferroelectric film 3, a source electrode 4 and a drain electrode 5 are disposed. On the first ferroelectric film 3, a second ferroelectric film 6 is formed so as to cover the source electrode 4 and the drain electrode 5. On the second ferroelectric film 6, a gate electrode 7 is provided in a region extending between the source electrode 4 and the drain electrode 5. It is assumed that in the first ferroelectric film 3, polarization reversal in the ferroelectric material occurs when a first coercive voltage is applied, while in the second ferroelectric film 6, polarization reversal in the ferroelectric material occurs when a second coercive voltage is applied. The coercive voltage is a voltage which is applied to the ferroelectric material to create an electric field (coercive electric field) of intensity required for the ferroelectric material polarization reversal.

In this embodiment, the constituent elements of the first ferroelectric film 3 may be different from those of the second ferroelectric film 6. Alternatively, the constituent elements of the first ferroelectric film 3 and the constituent elements of the second ferroelectric film 6 may be the same, in which their stoichiometric compositions are different from each other. More specifically, examples of the multilayer structure of the first and second ferroelectric films 3 and 6 (the first ferroelectric film 3/the second ferroelectric film 6) include a multilayer structure made of SrBi₂TaO₂/Bi₄Ti₃O₁₂ or BiₓTi₄₋ₓTi₃O₁₂Bi_{y}Ti_{4-y}Ti₃O₁₂ or other multilayer structures composed of combinations of various materials selected from metallic oxides having a perovskite crystalline structure or similar crystalline structure exhibiting ferroelectricity.

In the ferroelectric memory device having the above-described structure, the interface between the first ferroelectric film 3 and the second ferroelectric film 6 is the channel between the source electrode 4 and the drain electrode 5.

Hereinafter, a method for operating the semiconductor memory device according to the embodiment of the present invention will be described with reference to FIGS. 2 to 5. FIGS. 2 to 5 are schematic views for explaining the method for operating the semiconductor memory device according to the embodiment of the present invention.

(Preliminary Settings)

First spontaneous polarization 3A with electric charge P1 (C/cm²) per unit area is first induced in the first ferroelectric film 3.

To be specific, as shown in FIG. 2, a negative bias (−V*ₐₚₚ), for example, is applied to the gate electrode 7 with the potential at the conductive film 2 being the ground potential (GND). As a result, upward first spontaneous polarization 3A with electric charge P1 (C/cm²) per unit area is induced in the first ferroelectric film 3, and upward second spontaneous polarization 6A with electric charge P2 (C/cm²) per unit area is induced in the second ferroelectric film 6. At this time, the negative bias applied to the gate electrode 7, the dielectric constant and thickness of the first ferroelectric film 3, and the dielectric constant and thickness of the second ferroelectric film 6 are adjusted beforehand so that the potential difference allocated to the first ferroelectric film 3 is greater than the first coercive voltage and that the potential difference allocated to the second ferroelectric film 6 is greater than the second coercive voltage Also, at this time, it is preferable that the thickness of the first ferroelectric film 3 be greater than that of the second ferroelectric film 6

(Write Operation)

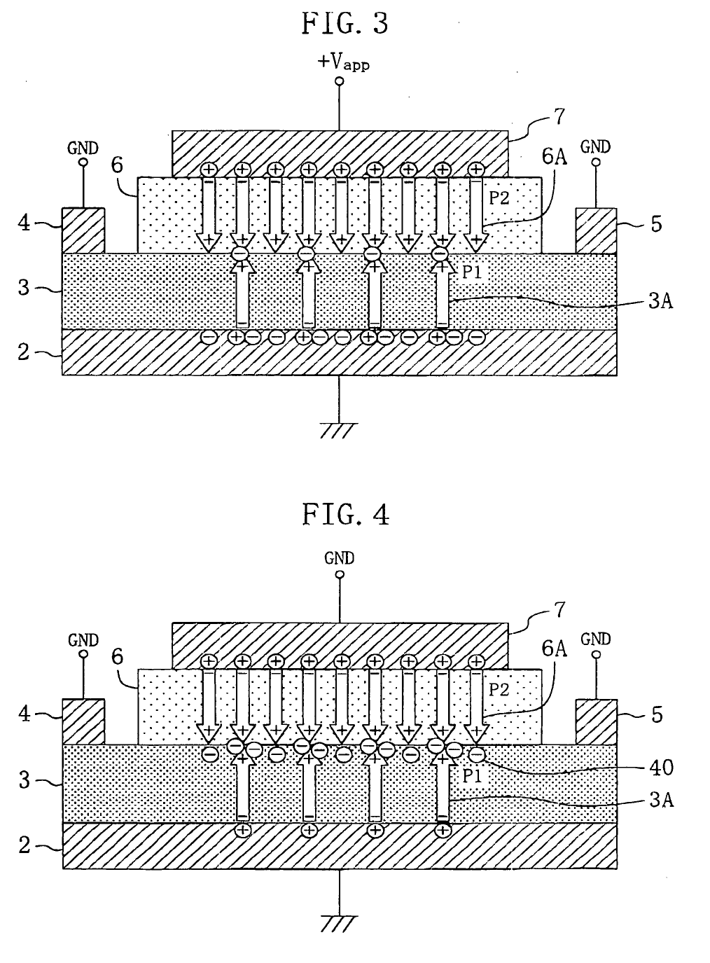

Data write to the semiconductor memory device having the above-described structure is performed as follows. As shown in FIG. 3, a positive pulse voltage (+Vₐₚₚ) is applied to the gate electrode 7 to thereby reverse only the second spontaneous polarization 6A in the second ferroelectric film 6 in the downward direction. In this process, the magnitude of the positive pulse voltage (+Vₐₚₚ) may be selected so that the potential difference allocated to the first ferroelectric film 3 is smaller than the first coercive voltage and that the potential difference allocated to the second ferroelectric film 6 is greater than the second coercive voltage.

Next, as shown in FIG. 4, the potential at the gate electrode 7 is set to the ground potential (GND). This causes two types of electrons 40 functioning differently to be present at the interface (i.e., in the channel) between the first ferroelectric film 3 and the second ferroelectric film 6: the electrons 40 of one type function as carriers for compensating for the electric charge P1 of the first spontaneous polarization 3A and the electrons 40 of the other type function as carriers for compensating for the electric charge P2 of the second spontaneous polarization 6A. In other words, the electrons 40 equal in amount to the electric charge (P1+P2) exist in the channel. The density (P1+P2) of the electrons 40 existing in the channel is thus higher than the electron density (P1 or P2) in the channel obtained in a case where either the first ferroelectric film 3 or the second ferroelectric film 6 is replaced with an insulating film. Therefore, even if the electrons 40 existing in the channel are confined and localized by the electric charge of the first spontaneous polarization 3A and the electric charge of the second spontaneous polarization 6A, the amount of overlap between the wave functions is increased by the fact that the distance between adjacent electrons 40 is shortened as compared with the conventional example, whereby interchange between the adjacent electrons 40 suddenly becomes easy. As a result, a sufficient amount of channel current is obtained.

Next, a negative pulse voltage (−Vₐₚₚ) is applied to the gate electrode 7 to thereby reverse only the second spontaneous polarization 6A in the second ferroelectric film 6 in the upward direction.

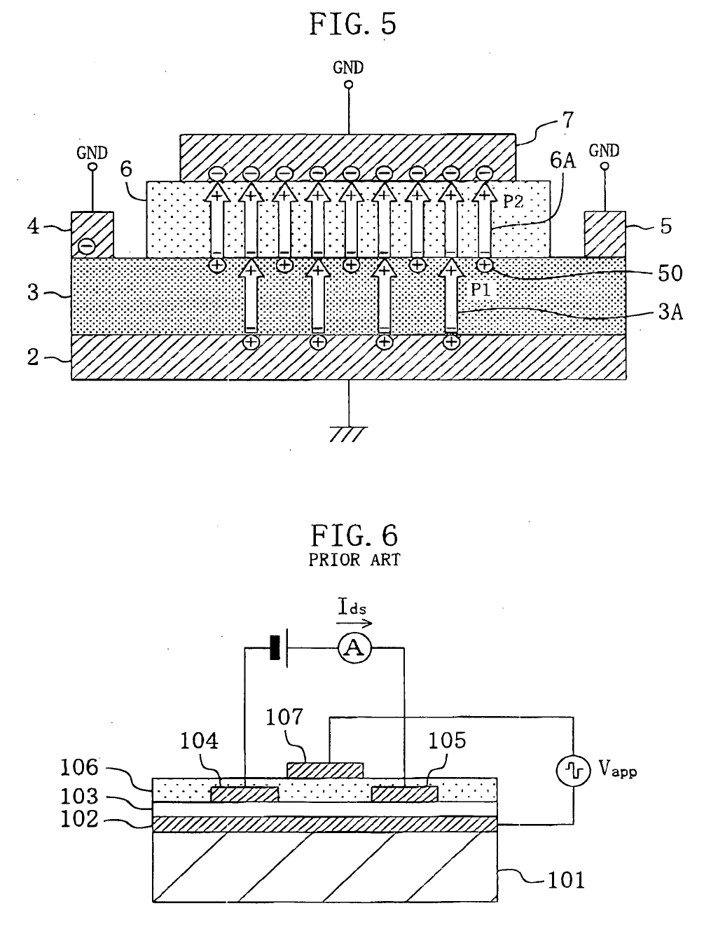

Subsequently, as shown in FIG. 5, the potential at the gate electrode 7 is set to the ground potential (GND), whereby atoms existing in the vicinity of the interface between the first ferroelectric film 3 and the second ferroelectric film 6 release electrons and are ionized positively. These positively ionized atoms 50 compensate for the electric charge of the upward second spontaneous polarization 6A in the second ferroelectric film 6. In this case, the electrons released from the atoms flow into the source electrode 4 and the drain electrode 5. Consequently, only the positively ionized atoms 50 and the ionic positive electric charge of the second spontaneous polarization 6A are left at the interface between the first ferroelectric film 3 and the second ferroelectric film 6. Therefore, there is no movable electric charge capable of moving at the interface i.e., in the channel, between the first ferroelectric film 3 and the second ferroelectric film 6.

(Read Operation)

Next, data read from the ferroelectric memory device will be described. It is possible to determine whether the direction of the second spontaneous polarization 6A in the second ferroelectric film 6 is upward or downward by reading changes in the resistance of the channel current when a bias voltage is applied between the source electrode 4 and the drain electrode 5, that is, by reading whether the amount of channel current flowing along the interface between the first ferroelectric film 3 and the second ferroelectric film 6 is large or small.

More specifically, when the direction of the second spontaneous polarization 6A is upward, the amount of chapel current flowing along the interface between the first ferroelectric film 3 and the second ferroelectric film 6 is small (i.e., the number of movable electrons is small), which results in increase in the channel resistance. On the other hand, when the direction of the second spontaneous polarization 6A is downward, the amount of channel current flowing along the interface between The first ferroelectric film 3 and the second ferroelectric film 6 is large (i.e., the number of movable electrons is very large (equal in amount to the electric charge (P1+P2)), which results in decrease in the channel resistance. In this manner, the channel current is changed depending upon the direction of the second spontaneous polarization 6A. It is thus possible to determine whether the direction of the second spontaneous polarization 6A in the second ferroelectric film 6 is upward or downward.

As described above, in the semiconductor memory device and the method for operating the semiconductor memory device according to the embodiment of the present invention, it is possible to induce those electrons 40 functioning as the carriers for compensating for the electric charge P1 of the first spontaneous polarization 3A and those electrons 40 functioning as the carriers for compensating for the electric charge P2 of the second spontaneous polarization 6A at the interface (i.e., in the channel) between the first ferroelectric film 3 and the second ferroelectric film 6. Therefore, even if the electrons 40 existing in the channel are confined and localized by the electric charge P1 of the first spontaneous polarization 3A and the electric charge P2 of the second spontaneous polarization 6A, the amount of overlap between the wave functions is increased by the fact that the distance between adjacent electrons 40 is shortened as compared with the conventional example, whereby interchange between the adjacent electrons 40 becomes easy. As a result, the localized electric charge carrier density is increased, such that a sufficient amount of channel current is obtained. This enables realization of data retention characteristic that is stable for a long time.

In the foregoing embodiment of the present invention, the first spontaneous polarization 3A in the first ferroelectric film 3 is first fixed and then the second spontaneous polarization 6A in the second ferroelectric film 6 is reversed. This may, however, be performed in the opposite way, in which the second spontaneous polarization 6A in the second ferroelectric film 6 is first fixed and then first spontaneous polarization 3A in the first ferroelectric film 3 is reversed. In that case, the potential differences allocated to the respective first and second ferroelectric films 3 and 6 are controlled by adjusting the first coercive voltage, dielectric constant, and thickness of the first ferroelectric film 3 and the second coercive voltage, dielectric constant, and thickness of the second ferroelectric film 6, whereby the present invention can be carried out in the manner as described above and the same effects as described above are therefore achievable.

Although the channel carriers are electrons in the foregoing embodiment of the present invention, positive holes may be dominant as the channel carriers. In that case, the electric polarity should be reversed in performing all of the procedural steps in the above-described operation method. By performing the procedural steps in this way, the present invention can be carried out as described above and the same effects as described above are therefore achievable.

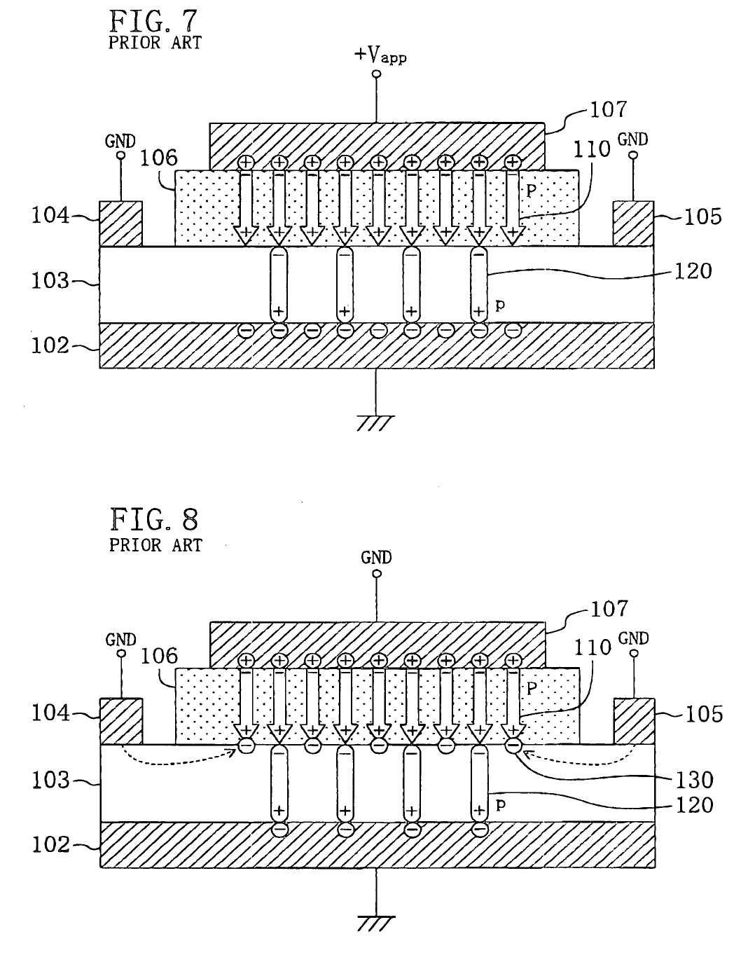

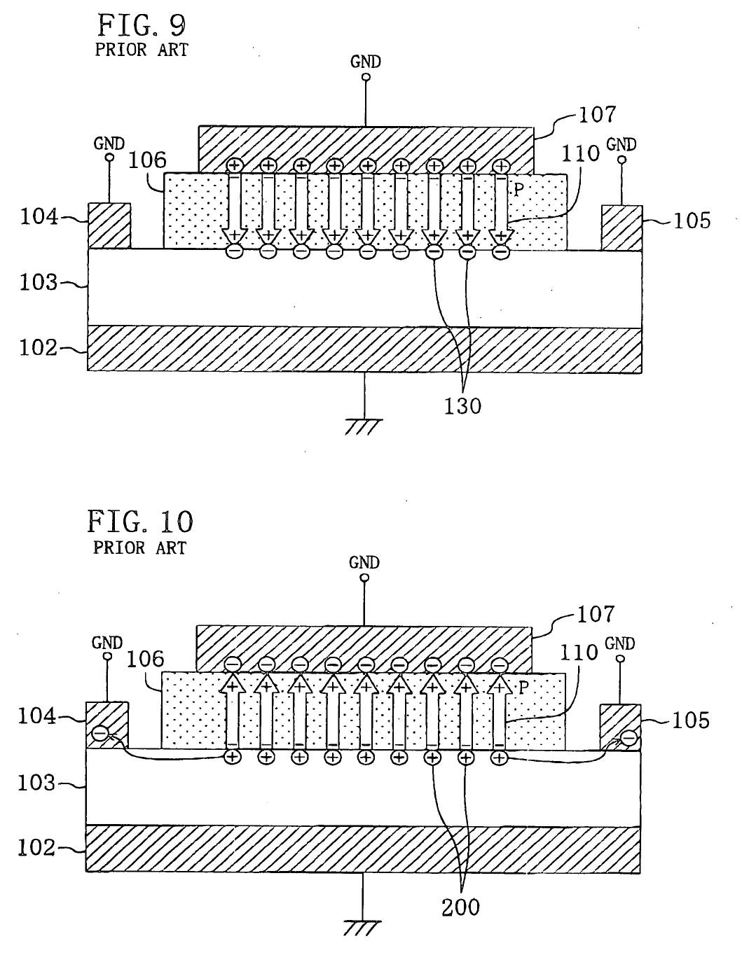

In the foregoing embodiment of the present invention, the typical case, in which the first coercive voltage for the first ferroelectric film 3 and the second coercive voltage for the second ferroelectric film 6 are different from each other, has been described. However, even in a special case, in which the first coercive voltage for the first ferroelectric film 3 and the second coercive voltage for the second ferroelectric film 6 are equal to each other and the first spontaneous polarization 3A in the first ferroelectric film 3 and the second spontaneous polarization 6A in the second ferroelectric film 6 are equal to each other, the present invention can be carried out in the manner as described above and the same effects as described above are therefore achievable. More specifically, in that special case, the polarization electric charge at the interface between the first ferroelectric film 3 and the second ferroelectric film 6 is neither too much nor too little. However, electron-hole pairs compensate for the foremost part of the first spontaneous polarization 3A in the first ferroelectric film 3 and the rearmost part of the second spontaneous polarization 6A in the second ferroelectric film 6 in order to satisfy a condition for the electric charge neutrality at the interface This allows both the electrons and holes to function as carriers, thereby achieving a carrier density higher than that obtained in the conventional example discussed with reference to FIGS. 8 to 10.

As described above, the present invention is applicable to ferroelectric memories capable of non-destructive read-out.

What is claimed is:

1. A semiconductor memory device, comprising:
a multilayer film including a first ferroelectric film and a second ferroelectric film;
means for creating an electric field which goes across the multilayer film; and
means for passing current along an interface between the first ferroelectric film and the second ferroelectric film and detecting the current.

2. The device of claim 1, wherein coercive voltage for the first ferroelectric film and coercive voltage for the second ferroelectric film are different from each other.

3. The device of claim 1, wherein the means for creating an electric field includes a pair of electrodes provided so as to face each other with the multilayer film interposed therebetween.

4. The device of claim 1, wherein the means for passing current along the interface and detecting the current is electrically connected to the first ferroelectric film or the second ferroelectric film and includes a pair of electrodes, in between the interface along which the current passes exists.

5. A method for operating a semiconductor memory device, wherein modulation of current passing along an interface in a multilayer film is used; and
the current modulation is performed by creating an electric field, which goes across the multilayer film including a first ferroelectric film and a second ferroelectric film having different coercive voltages, and by reversing spontaneous polarization in either one of the first ferroelectric film and the second ferroelectric film.

6. The method of claim 5, wherein before the spontaneous polarization in either one of the first ferroelectric film and the second ferroelectric film is reversed, spontaneous polarization is induced in the other one of the first ferroelectric film and the second ferroelectric film, whose spontaneous polarization induced is never reversed independent of the polarization reversal of the other ferroelectric film.
